(19) United States
(12) Patent Application Publication
(10) Pub. No.: US 2026/0001053 A1
(43) Pub. Date: Jan. 1, 2026

(54) MANIFOLD ASSEMBLIES, REACTOR SYSTEMS INCLUDING MANIFOLD ASSEMBLIES, AND ASSOCIATED METHODS FOR SUPPLYING A GAS MIXTURE TO A REACTION CHAMBER

(71) Applicant: ASM IP Holding B.V., Almere (NL)

(72) Inventors: Jing Yuan, Phoenix, AZ (US); Wentao Wang, Chandler, AZ (US); Parneet Singh Chawla, Phoenix, AZ (US); Aditya Chaudhury, Tempe, AZ (US); Junwei Su, Chandler, AZ (US); Alexandros Demos, Scottsdale, AZ (US)

(21) Appl. No.: 19/250,158

(22) Filed: Jun. 26, 2025

Related U.S. Application Data
(60) Provisional application No. 63/665,763, filed on Jun. 28, 2024.

(51) Int. Cl. B01J 4/00; C09K 13/08

(52) U.S. Cl. CPC B01J 4/002; C09K 13/08

(57) ABSTRACT

Manifold assemblies, reactor systems including manifold assemblies and associated method for supplying a gas mixture to a reaction chamber employing manifold assemblies are disclosed. The manifold assemblies disclosed include a first gas injection port for introducing a first gas into a manifold body and a second gas injection port for introducing a second gas into the manifold body and a plenum for mixing the first gas and the second gas. Reactor systems including manifold assemblies are disclosed and methods for supplying a gas mixture to reaction chamber employing a manifold assembly are disclosed.

### CROSS-REFERENCE TO RELATED APPLICATION(S)

This application claims the benefit of U.S. Provisional Application 63/665,763 filed on Jun. 28, 2024, the entire contents of which are incorporated herein by reference.

### FIELD

The present disclosure relates generally to the field of semiconductor processing apparatus and associated processing methods and to the field of device and integrated circuit manufacture. More particularly the present disclosure generally relates to manifold assemblies for providing a gas mixture to a reaction chamber of a reactor system.

### BACKGROUND

Gas-phase reactors, such as chemical vapor etch (CVE), chemical vapor deposition (CVD), plasma-enhanced CVD (PECVD), plasma-enhanced CVE (PECVE), atomic layer deposition (ALD), atomic layer etch (ALE), and the like can be used for a variety of applications, including etching and depositing materials on a substrate surface. For example, gas-phase reactors can be used to deposit and/or etch layers on a substrate to form semiconductor devices, flat panel display devices, photovoltaic devices, microelectromechanical systems (MEMS), and the like.

A typical gas-phase reactor system includes one or more reactors, each reactor including one or more reaction chambers; one or more precursor and/or reactant gas sources fluidly coupled to the reaction chamber(s); one or more carrier and/or purge gas sources fluidly coupled to the reaction chamber(s); one or more gas distribution systems to deliver gases (e.g., the precursor/reactant gas(es) and/or carrier or purge gas(es)) to a surface of a substrate within a reaction chamber; and at least one exhaust source fluidly coupled to the reaction chamber(s).

In some processes carried out in reaction chambers, it may be desirable to provide two or more gases to the reaction chamber at the same time or overlapping in time. For example, two, three, four or more gases can be separately provided to a reaction chamber at the same time or overlapping in time. While such apparatus may be suitable for some applications, providing gases separately to the reaction chamber may result in undesired variability in a process. Accordingly, improved apparatus for providing a gas mixture to a reaction chamber are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to manifold assemblies for providing a gas mixture to a reactor or a reaction chamber, to systems including the manifold assemblies, and to methods of using the manifold assemblies and systems. The assemblies, systems, and methods can be used in connection with a variety of applications, including, for example, the manufacturing of electronic devices. While the ways in which various embodiments of the present disclosure address drawbacks of prior methods and systems are discussed in more detail below, in general, various embodiments of the disclosure provide improved assemblies, systems, and methods suitable for providing a mixture of two or more gases to a reaction chamber. Exemplary manifold assemblies can, for example, provide a uniform, particle free, gas mixture to a reaction chamber.

Various embodiments of the disclosure provide a manifold assembly comprising: a manifold body having a central axis and comprising a bore configured for receiving a first gas and outputting a gas mixture to a reaction chamber, the manifold body comprising an inlet block mounted to a mixer block which is in turn mounted to a transfer block, wherein the inlet block, the mixer block, and the transfer block cooperate to at least partially to define the bore; a first channel disposed between a lower surface of the inlet block and an upper surface of the mixer block and extending in a plane intersecting the central axis; a gas inlet channel disposed within the mixer block and in fluid communication with the first channel, the gas inlet channel configured for injecting a second gas into the manifold assembly; a second channel disposed between a lower surface of the mixer block and an upper surface of the transfer block and extending in a plane intersecting the central axis, wherein the second channel comprises a mixer outlet disposed between an inner lower surface of the mixer block and the upper surface of the transfer block; a mixer conduit disposed within the mixer block between the first channel and the second channel and having a conduit inlet in fluid communication with the first channel and a conduit outlet in fluid communication with the second channel; a gas mixing plenum disposed between the inner lower surface of the mixer block and the upper surface of the transfer block, the gas mixing plenum in fluid communication with both the mixer outlet and the bore and configured to mix the first gas received from the bore with the second gas received from the mixer outlet to form the gas mixture; and a transfer conduit disposed within the transfer block and comprising a portion of the bore, the transfer conduit having transfer inlet in fluid communication with the gas mixing plenum and a transfer outlet configured to couple with the reaction chamber to enable the output of the gas mixture to the reaction chamber.

In some embodiments the first channel is defined by a groove formed in the upper surface of the mixer block and by the lower surface of the inlet block.

In some embodiments the first channel is disposed at least partially about the central axis to direct a second gas circumferentially relative to the bore.

In some embodiments the first channel follows a circular curvature.

In some embodiments the first channel extends through an arc of at least 180°.

In some embodiments the first channel extends through an arc of about 240°.

In some embodiments the second channel is at least partially defined by an annular groove formed in the lower surface of the mixer block and by the upper surface of the transfer block.

In some embodiments the first channel and the second channel are radially aligned with each other

In some embodiments the mixer block comprises a single body of metal.

Various embodiments of the disclosure provide a reactor system comprising: a reaction chamber; a manifold assembly coupled with and in fluid communication with the reaction chamber, the manifold assembly comprising: a manifold body having a central axis and comprising a bore configured for receiving a first gas into the manifold assembly and outputting a gas mixture to the reaction chamber, the manifold body comprising an inlet block mounted to a mixer block which is in turn mounted to a transfer block, where the inlet, the mixer, and the transfer mounted blocks cooperate to at least partially to define the bore; a first channel disposed between a lower surface of the inlet block and an upper surface of the mixer block and extending in a plane intersecting the central axis; a gas inlet channel disposed within the mixer block and in fluid communication with the first channel, the gas inlet channel configured for injecting a second gas into the manifold assembly; a second channel disposed between a lower surface of the mixer block and an upper surface of the transfer block and extending in a plane intersecting the central axis, wherein the second channel comprises a mixer outlet disposed between an inner lower surface of the mixer block and the upper surface of the transfer block; a mixer conduit disposed within the mixer block between the first channel and the second channel and having a conduit inlet in fluid communication with the first channel and a conduit outlet in fluid communication with the second channel; a gas mixing plenum disposed between the inner lower surface of the mixer block and the upper surface of the transfer block, the gas mixing plenum in fluid communication with both the mixer outlet and the bore and configured to mix the first gas received from the bore with the second gas received from the mixer outlet to form the gas mixture; and a transfer conduit disposed within the transfer block and comprising a portion of the bore, the transfer conduit having transfer inlet in fluid communication with the gas mixing plenum and a transfer outlet configured to couple with the reaction chamber to enable the output of the gas mixture to the reaction chamber; a gas source system comprising two or more source vessels, the gas source system being in fluid communication with a first gas injection port and a second first gas injection port, the first gas injection port being coupled to a portion of the bore disposed within the inlet block and the second gas injection port being coupled to the gas inlet channel disposed within the mixer block; a vacuum source in fluid communication with the reaction chamber and configured for removing an excess of the gas mixture from the reaction chamber; and a controller linked to at least the gas source system, the reaction chamber, the vacuum source, and a first valve configured for controlling flow of the first gas to the manifold assembly and a second valve configured for controlling flow of the second gas to the manifold assembly.

In some embodiments the first channel extends through an arc of about 240 degrees.

In some embodiments the first channel and the second channel are radially aligned with each other.

In some embodiments the reaction chamber further comprising a gas distribution assembly fluidly connected to the transfer outlet of the manifold assembly.

In some embodiments the reaction chamber is configured for performing chemical vapor etch processes.

In some embodiments the gas source system further comprises a gas manifold comprising a manifold input and manifold output, wherein the manifold input is in fluid communication with at least two of the source vessels and the manifold output is in fluid communication with the first gas injection port.

In some embodiments the reactor system further comprising an additional reaction chamber coupled to the reaction chamber by a transfer chamber, the transfer chamber constructed and arranged to transfer a substrate from the reaction chamber to the additional reaction chamber in a controlled environment.

In some embodiments the additional reaction chamber is configured for performing deposition processes.

Various embodiments of the disclosure provide method of supplying a gas mixture to a reaction chamber, the method comprising: supplying a first gas to an input of a manifold body having a central axis and comprising a bore configured for receiving the first gas, the manifold body comprising an inlet block mounted to a mixer block which is in turn mounted to a transfer block, wherein the inlet block, the mixer block, and the transfer block cooperate to at least partially to define the bore; supplying a second gas to a gas inlet channel disposed within the mixer block and in fluid communication with a first channel, wherein the first channel is disposed between a lower surface of the inlet block and an upper surface of the mixer block and extending in a plane intersecting the central axis; feeding the second gas from the first channel through a mixer conduit disposed within the mixer block to a second channel, wherein the mixer conduit is in fluid communication with the first channel and the second channel and the second channel is disposed between a lower surface of the mixer block and an upper surface of the transfer block and extends in a plane intersecting the central axis and wherein the second channel comprises a mixer outlet disposed between an inner lower surface of the mixer block and the upper surface of the transfer block; mixing the first gas and the second gas to form a gas mixture in a gas mixing plenum disposed between the inner lower surface of the mixer block and the upper surface of the transfer block, wherein the gas mixing plenum is in fluid communication with both the mixer outlet of the second channel and the bore; transferring the gas mixture to transfer conduit disposed within the transfer block wherein the transfer conduit has an inlet in fluid communication with the gas mixing plenum; and outputting the gas mixture from an outlet of the transfer conduit to a reaction chamber coupled to the manifold body.

In some embodiments the reaction chamber is configured to perform chemical vapor etch processes.

In some embodiments the first gas comprises one or more of argon, hydrogen, and water vapor, the second gas comprises one or more of ammonia and hydrofluoric acid vapor.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a manifold assembly in accordance with one or more embodiments of the disclosure.

FIG. 2 illustrates an isometric view of a mixer block including an upper surface view in accordance with one or more embodiments of the disclosure.

FIG. 3 illustrates an isometric view of a mixer block including a lower surface view in accordance with one or more embodiments of the disclosure.

FIG. 4 illustrates an isometric cut-away view of a mixer block in accordance with one or more embodiments of the disclosure.

FIG. 5 illustrates a plan view of an upper surface of a mixer block in accordance with one or more embodiments of the disclosure.

FIG. 6 illustrates a plan view of a lower surface of a mixer block in accordance with one or more embodiments of the disclosure.

FIG. 7 illustrates an expanded cut-away cross-sectional view of a portion of a manifold assembly in accordance with one or more embodiments of the disclosure.

FIG. 8 illustrates a transfer block in accordance with one or more embodiments of the disclosure.

FIG. 9 illustrates a reactor system in accordance with one or more embodiments of the disclosure.

FIG. 10 illustrates a method for supplying a gas mixture to a reaction chamber in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

In this disclosure, “gas” can include material that is a gas at normal temperature and pressure (NTP), a vaporized solid and/or a vaporized liquid, and can be constituted by a single gas or a mixture of gases, depending on the context. A gas other than a process gas, i.e., a gas introduced without passing through a gas distribution assembly, other gas distribution device, or the like, can be used for, e.g., sealing the reaction space, and can include a seal gas, such as a rare gas.

The term “precursor” can refer to a compound that participates in the chemical reaction that produces another compound. The term “reactant” can be used interchangeably with the term precursor. The term “inert gas” can refer to a gas that does not take part in a chemical reaction and/or does not become a part of a layer to an appreciable extent. Exemplary inert gases include helium and argon and any combination thereof. In some cases, molecular nitrogen and/or hydrogen can be an inert gas. A carrier gas can be or include an inert gas.

As used herein, the term “substrate” may refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as GaAs, and can include one or more layers overlying or underlying the bulk material. Further, the substrate can include various topologies, such as recesses, lines, and the like formed within or on at least a portion of a layer of the substrate.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

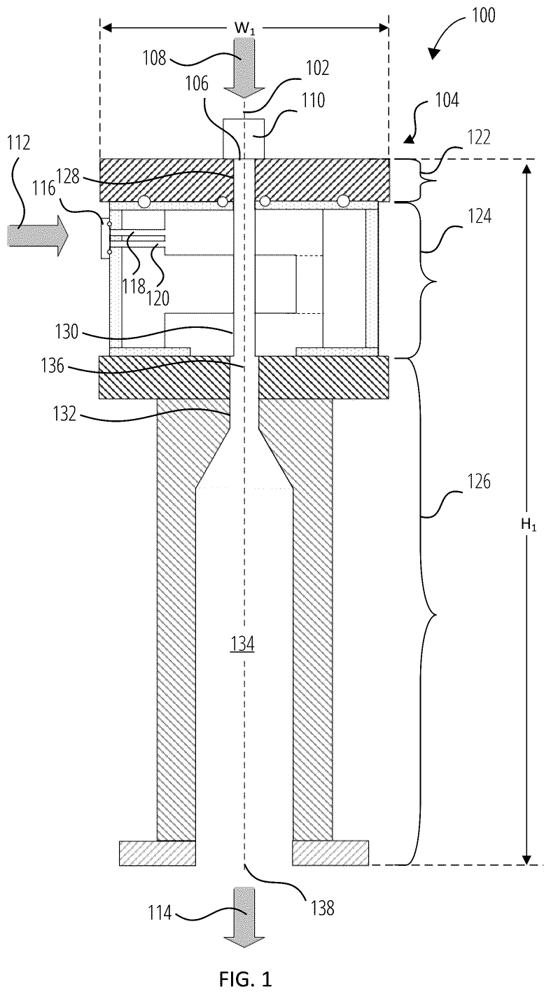

Turning now to the figures, FIG. 1 illustrates a cross-sectional view of a manifold assembly 100 in accordance with various embodiments. In brief, the manifold assembly 100 can be constructed and arranged to receive a first gas (as illustrated by first gas flow 108) and a second gas (as illustrated by second gas flow 112). In various embodiments the manifold assembly 100 is constructed and arranged (as described in detail below) to mix together the first gas and the second gas and subsequently output a gas mixture (as illustrated by gas mixture flow 114). The various embodiments of the disclosure provide manifold assemblies capable of outputting a uniform gas mixture having a low particle count while reducing dead volumes, gas flow recirculation, and gas residence time within the manifold assembly. For example, the uniformity and purity of the gas mixture flow output by manifold assemblies provided can improve the quality of processes performed within a reaction chamber coupled to the manifold assemblies. In addition, the high-quality gas mixture output by the manifold assemblies provided can be achieved with an assembly having a compact and efficient form factor.

In accordance with examples of the disclosure, the manifold assembly 100 can have a central axis 102 and comprise a manifold body 104. The manifold body 104 can include a bore 106 (e.g., a hollow bore) constructed and arranged to receive a first gas (as illustrated by first gas flow 108) at an upper extent of the bore 106. For example, the manifold assembly 100 can comprise a first gas injection port 110 configured to couple an inlet of the bore 106 with one or more gas conduits to enable the injection of the first gas into the manifold assembly 100. The manifold assembly 100 can also include a second gas injection port 116 configured to couple one or gas inlet channels with one or more gas conduits to enable the injection of the second gas into the manifold assembly 100. For example, the second gas injection port 116 can couple external gas supply lines (not illustrated) with a first gas inlet channel 118 and second gas inlet channel, as illustrated in FIG. 1. In various embodiments the gas inlet channels (e.g., 118 and 120) can introduce the second gas into the manifold assembly 100. In some embodiments the first gas inlet channel 118 and the second gas inlet channel 120 can introduce two or more gases into the manifold body 104. In such embodiments the second gas (as indicted by second gas flow 112) can comprise two or more gases. In such embodiments the manifold assembly 100 can be configured to mix the two or more component gases of the second gas (e.g., as provided by gas inlet channel 118 and 120) prior to mixing the second gas with the first gas injected into the bore 106.

In accordance with examples of the disclosure, the manifold body 104 can comprise an inlet block 122, a mixer block 124, and a transfer block 126. In some embodiments one or more of the inlet block 122, the mixer block 124, and the transfer block 126 may be fabricated from a single body of metal, such as, aluminum for example. In such embodiments one or more of the inlet block 122, the mixer block 124, and the transfer block 126 may be coated with an additional metal, such as, nickel, for example. In some embodiments the inlet block 122, the mixer block 124 and the transfer block can be mounted to one another to form the manifold assembly 100. In some embodiments the inlet block 122 can mounted to the mixer block 124, and the mixer block 124 (with the mounted inlet block 122) can be mounted to the transfer block 126. In such embodiments the inlet block 122, the mixer block 124, and the transfer block 126 cooperate to at least partially define the bore 106. In various embodiments an inlet bore 128 can be disposed within the inlet block 122, a mixer bore 130 can be disposed within the mixer block 124, and a transfer bore 132 can be disposed within the transfer block 126. In such embodiments the inlet bore 128, the mixer bore 130, and the mixer bore 130 together at least partially define the bore 106. In some embodiments the inlet bore 128, the mixer bore 130, and the mixer bore 130 can be coaxial with one another. In some embodiments the inlet bore 128, the mixer bore 130, and the mixer bore 130 and can be aligned about the central axis 102.

In accordance with examples of the disclosure, a lower surface of the inlet block 122 can contact an upper surface of the mixer block 124 upon mounting the inlet block and mixer block together, as described in greater detail below. In addition, a lower surface of the mixer block 124 can contact an upper surface of the transfer block upon mounting the mixer block and the transfer block together.

In some embodiments the manifold body 104 has width to height ratio (W1:H1) equal to or greater than 1:1, equal to or greater than 1:2, equal to or greater than 1:3, equal to or greater than 1:4, equal to or greater than 1:5, equal to or greater than 1:7, or equal to or greater than 1:10.

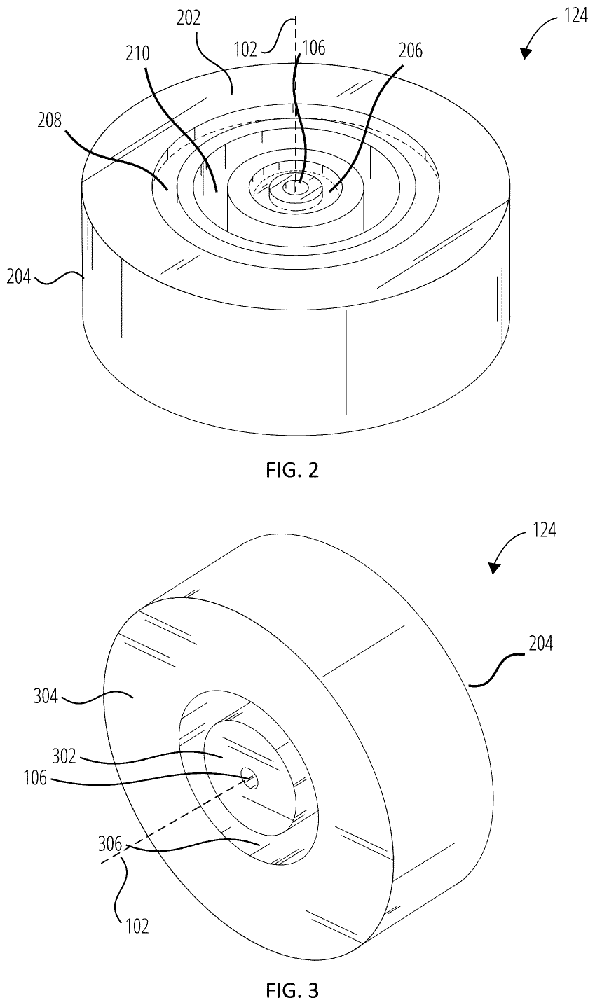

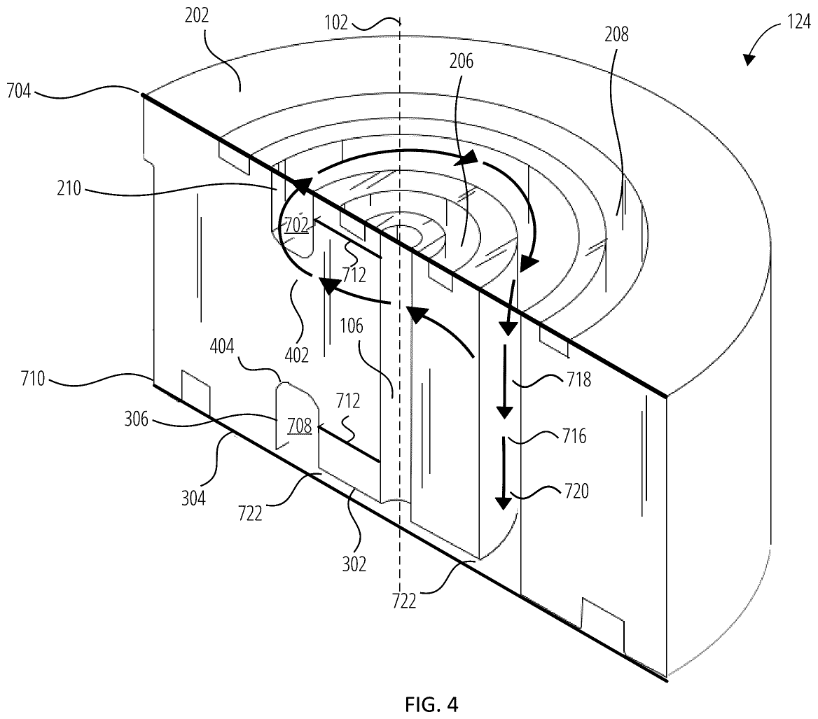

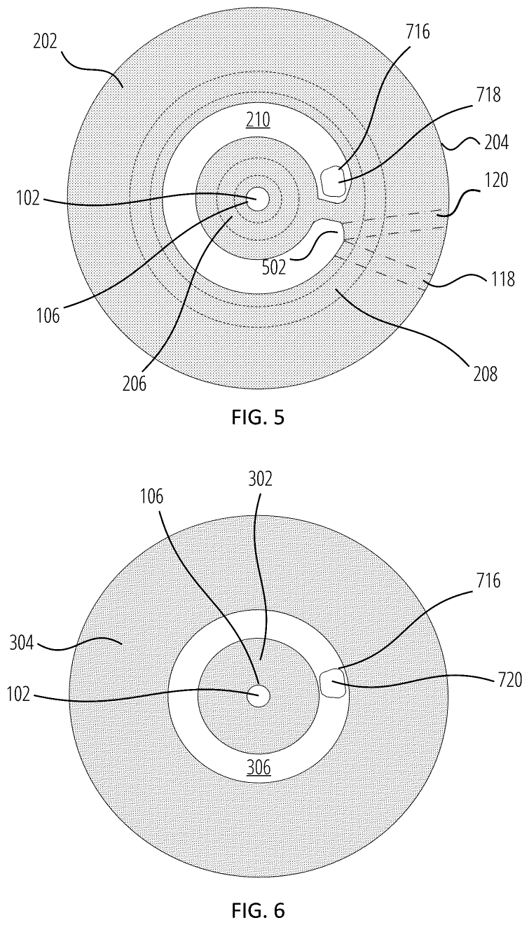

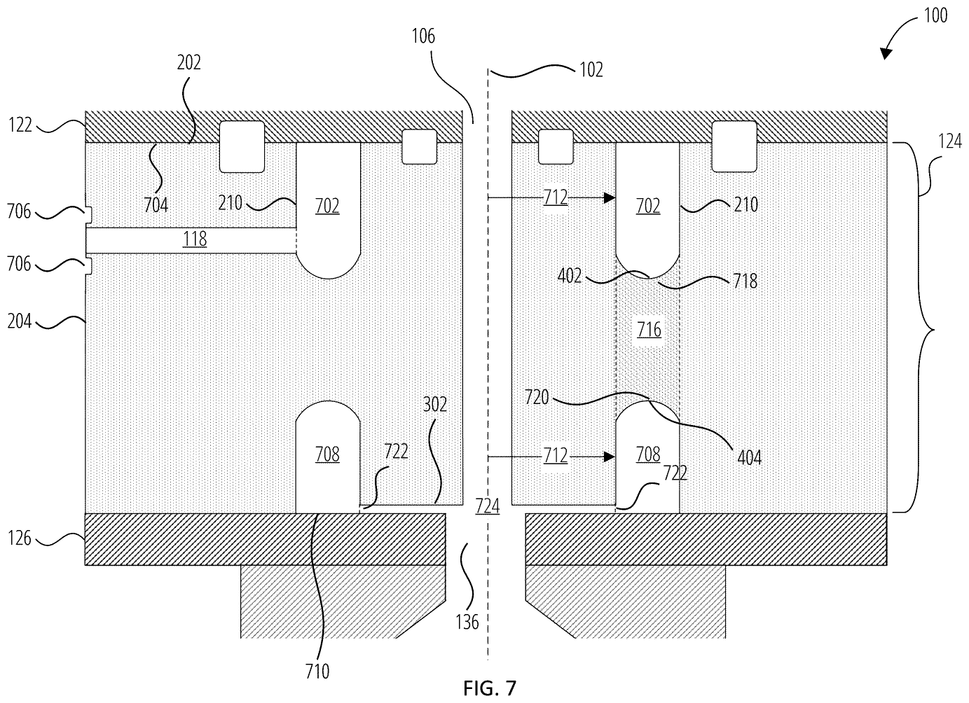

FIGS. 2-7 illustrate various views of the mixer block 124 (and adjacent mounted blocks) of the manifold assembly 100 in more detail. For example, FIG. 2 illustrates an isometric view of an upper surface of the mixer block 124, FIG. 3 illustrates an isometric view of a lower surface of the mixer block 124, FIG. 4 illustrates an isometric cut-away view of the mixer block 124, FIG. 5 illustrates a plan view of an upper surface of the mixer block 124, FIG. 6 illustrates a plan view of a lower surface of the mixer block 124, and FIG. 7 illustrates an expanded cut-away cross-sectional view of a portion of a manifold assembly including the mixer block and adjacent mounted elements in accordance with one or more embodiments of the disclosure.

In various embodiments the mixer block 124 can comprise an upper surface 202, an inner lower surface 302 and outer lower surface 304, as well as a side surface 204 (i.e., a sidewall of the mixer block). A portion of the bore 106 (e.g., the mixer bore) extends through the mixer block 124 from the upper surface of the mixer block 202 to the inner lower surface 302. A first recess 206 and a second recess 208 can be disposed in the upper surface 202. The first recess 206 and second recess 208 can be annular recesses disposed radially around the bore 106 and each can be configured for housing a sealing member.

In accordance with examples of the disclosure, a groove 210 can be disposed in the upper surface 202 of the mixer block 124, see for example FIG. 2 and FIG. 5. In some embodiments the groove 210 can be disposed at least partially about the central axis 102. In some embodiments the groove 210 can be disposed radially at least partially around the bore 106. In some embodiments the groove 210 follows a circular curvature. In one aspect the groove 210 may extend through an arc of at least 180 degrees. In another aspect the groove 210 may extend through an arc of about 240 degrees. In another aspect the groove 210 may comprise a partial-annular groove. In another aspect the groove 210 may be coaxial with the bore 106. In another aspect the groove 210 may be coaxial with the central axis 102. In some embodiments the groove 210 may be coaxial with the bore 106 and the central axis 102. In some embodiments the groove 210 comprises a floor 402 (see FIG. 4) having a curved surface, as viewed from a side cross-section.

In accordance with examples of the disclosure, the groove 210 can be disposed at least partially about the central axis 102 to direct the second gas circumferentially relative to the bore 106. In such examples the groove 210 can be disposed radially at least partially around bore 106 to direct the second gas circumferentially relative to the bore 106. In some embodiments the groove 210 follows a circular curvature.

As illustrated in FIG. 3, FIG. 5 and FIG. 6, the mixer block 124 can comprise an inner lower surface 302 and an outer lower surface 304. The inner lower surface 302 can comprise a circular surface which can be coaxial with the bore 106 (i.e., mixer bore 130), as illustrated in FIG. 6. The outer lower surface 304 can comprise an annular surface which can be coaxial with both the inner lower surface 302 and the bore 106. In some embodiments the inner lower surface 302 and the outer lower surface 304 are positioned on two different planes. For example, the outer lower surface 304 120 can extend in a first plane intersecting the central axis 102 and the inner lower surface 302 can extend in a second plane intersecting the central axis 102, the first plane and the second plane being vertically separated, as described below.

In accordance with examples of the disclosure, an annular groove can be disposed between the outer lower surface and the inner lower surface of the mixer block. As illustrated in FIG. 3 and FIG. 6 the annular groove 306 can be disposed in a lower surface of the mixer block 124. In various embodiments the annular groove 306 can be disposed between the inner lower surface 302 and the outer lower surface 304 of the mixer block 124. In some embodiments the annular groove 306 can be disposed radially about the central axis 102. In some embodiments the annular groove 306 can be disposed radially around the bore 106 (i.e., mixer bore). In some embodiment the annular groove 306 may be coaxial with the bore 106. In some embodiment the annular groove 306 may be coaxial with the central axis 102. In some embodiment the annular groove 306 may be coaxial with the bore 106 and the central axis 102. In some embodiments the annular groove 306 comprises a ceiling 404 (as illustrated in FIG. 4) having a curved upper surface, as viewed from a side cross-section.

In accordance with examples of the disclosure, the groove disposed in the upper surface of the mixer block and the lower surface of the inlet block can together define a first channel. For example, FIG. 7 illustrates an expanded cut-away cross-sectional view of a portion of the manifold assembly 100 showing the mixer block 124 mounted to both the inlet block 122 and the transfer block 126. As illustrated in FIG. 7 the inlet block lower surface 704 and the groove 210 disposed in the upper surface 202 of the mixer block 124 together define a first channel 702.

In accordance with examples of the disclosure, the first channel 702 can be disposed between a lower surface 704 of the inlet block 122 and an upper surface 202 of the mixer block 124, see for example FIG. 4 where the bolded line represents the lower surface 704 of the inlet block. In such examples the first channel 702 may extend in a plane intersecting the central axis 102, wherein the first channel 702 is defined by the groove 210 formed in the upper surface (202) of the mixer block 124 and the lower surface (704) of the inlet block 122. In such examples the first channel 702 can be disposed at least partially about the central axis 102 to direct a second gas circumferentially relative to the bore 106 (e.g., the mixer bore portion of the bore 106). In such embodiments the first channel 702 can be disposed radially at least partially around the bore 106 to direct the second gas circumferentially relative to the bore 106.

In some embodiments the first channel 702 follows a circular curvature (see FIG. 4 and FIG. 5). In some embodiments the first channel 702 extends through an arc of at least 180 degrees. In some embodiments the first channel 702 may extend through an arc of about 240 degrees. In some embodiments the first channel 702 may comprise a partial-annular channel. In some embodiment the first channel 702 may be coaxial with the bore 106. In some embodiment the first channel 702 may be coaxial with the central axis 102. In some embodiment the first channel 702 may be coaxial with the mixer bore 130 and the central axis 102. In some embodiments the first channel 702 comprises a floor 402 (see FIG. 4 and FIG. 7) having a curved lower surface, as viewed from a side cross-section. In some embodiments the first channel 702 comprises a partially annular channel (FIG. 4) which is revolved about the longitudinal axis (i.e., perpendicular to the central axis 102) in a range of 90° to 360°. In some embodiments the first channel 702 has width to depth ratio (W:D) equal to or greater than 1:1, equal to or greater than 2:1, equal to or greater than 3:1, or equal to or greater than 5:1.

In accordance with examples of the disclosure, one or more gas inlet channels can be disposed within the mixer block. For example, FIG. 7 illustrates a first gas inlet channel 118 disposed within the mixer block 124. In such examples the first gas inlet channel 118 is configured for the introduction of the second gas into the manifold assembly 100. In some embodiments the mixer block 124 may comprise a first gas inlet channel 118 and a second gas inlet channel 120 (as illustrated in FIG. 1), the first and second gas inlet channels enabling the introduction of two or more gases (i.e., the component gases of the second gas) into the manifold assembly and particularly into the mixer block 124. In such embodiments two separate gas inlet channels (e.g., a first gas inlet channel 118 and a second gas inlet channel 120) can be disposed within the mixer block 124. For example, the gas inlet channels (118 and 120) can be coupled with a second gas injection port 116 (see FIG. 1) disposed on a side surface 204 of the mixer block 124. FIG. 7 illustrates recesses 706 disposed in the side surface 204 of the mixer block 124, the recesses 706 being configured to receiving a sealing member for coupling a second gas injection port to the mixer block 124. In such examples, the one or more gas inlet channels (such as the first gas inlet channel 118) can be in fluid communication with the first channel 702 disposed within the mixer block 124.

In accordance with examples of the disclosure, the annular groove disposed in a lower surface of the mixer block and the upper surface of the transfer block can at least partially define a second channel. For example, FIG. 7 illustrates the mixer block 124 mounted to the transfer block 126. As illustrated in FIG. 7 a second channel 708 can be disposed between a lower surface of the mixer block 124 (e.g., outer lower surface 304 and inner lower surface 302) and an upper surface of the transfer block 126 (e.g., transfer block upper surface 710). In such examples the second channel 708 can be disposed between the outer lower surface 304 of the mixer block 124 and the inner lower surface 302 of the mixer block 124.

In accordance with examples of the disclosure, the second channel 708 can be disposed radially about the central axis 102, see for example FIG. 6 where the annular groove 306 represents the second channel 708 upon mounting with the transfer block. In some embodiments the second channel 708 can be disposed radially around the bore 106 (i.e., mixer bore 130). In some embodiments the second channel 708 may be coaxial with the bore 106. In some embodiment the second channel 708 may be coaxial with the central axis 102. In some embodiment the second channel 708 may be coaxial with both the bore 106 and the central axis 102. In some embodiments the second channel 708 comprises a ceiling 404 (see FIG. 4 and FIG. 7) having a curved surface, as viewed from a side cross-section. In some embodiments the second channel 708 may extend in a plane intersecting the central axis 102. In some embodiments the second channel 708 has width to depth ratio (W:D) equal to or greater than 1:1, equal to or greater than 2:1, equal to or greater than 3:1, or equal to or greater than 5:1.

In various embodiments the second channel 708 further comprises a second channel outlet. As illustrated in FIG. 4 and FIG. 7 the second channel 708 includes a second channel outlet 722 which can comprise an outlet slit disposed at the base of the second channel 708. In some embodiments the second channel outlet 722 is at least partially define by the inner lower surface 302 and the outer lower surface 304 of the mixer block 124. As previously described the inner lower surface 302 and outer lower surface 304 are vertically separated, the separation between the two surfaces forming the second channel outlet 722. In some embodiments inner lower surface 302 and outer lower surface 304 are vertically separated by a distance of more than 1 mm, more than 2 mm, more than 3 mm, more than 4 mm, more than 5 mm, or between 1 and 5 mm. Therefore, in some embodiments second channel outlet 722 has a slit height of more than 1 mm, more than 2 mm, more than 3 mm, more than 4 mm, more than 5 mm, or between 1 and 5 mm. In some embodiments the second channel outlet 722 comprises an annular outlet slit. In such embodiments the annular outlet slit can be disposed radially around the central axis 102. In various embodiments the second channel outlet 722 is sized and arranged to inject the second gas, previously introduced into first channel, and transferred to the second channel, into a gas mixing plenum, as described in detail below.

In accordance with examples of the disclosure, the first channel 702 and the second channel 708 can be radially aligned with each other. In such examples the first channel 702 may positioned at a first radial distance 712 from the central axis 102 (see FIG. 4 and FIG. 7) and the second channel 708 may be positioned at the first radial distance 712 from the central axis 102. In other words, the first channel 702 and the second channel 708 can both be positioned within the mixer block at the same radial distance from the central axis (and/or the bore 106). In some embodiments the width of the first channel 702 and the width of the second channel 708 may be equal, or substantially equal. In some embodiments the second channel 708 can be disposed radially about the central axis 102 to direct the second gas (as received from the first channel 702) circumferentially relative to the bore 106 (e.g., the mixer bore portion of the bore 106), as described below.

In various embodiments a mixer conduit may be disposed within the mixer block. In such embodiments the mixer conduit can be disposed between the first channel and the second channel. As illustrated in FIG. 4 and FIG. 7 a mixer conduit 716 can be disposed between the first channel 702 and the second channel 708. In various embodiments a gas (i.e., the second gas) can be introduced via gas inlet channel 118 and injected into the first channel 702. In such embodiments the gas can be directed circumferentially relative to the bore 106 from the point where the gas inlet channel 118 intercepts the first channel 702. In some embodiments the second gas can be directed around the arc of the first channel 702 to a conduit inlet 718 of the mixer conduit 716 (as illustrated in FIG. 4 by the bold arrows representing the flow of the second gas within the mixer block). In various embodiments the mixer conduit 716 (FIG. 4 and FIG. 7) has a conduit inlet 718 which can be disposed in the floor 402 of the first channel 702 and a conduit outlet 720 which is disposed in the ceiling 404 of the second channel 708. In such embodiments the mixer conduit 716 provides a flow path for the second gas to traverse from the first channel 702 to the second channel 708.

In accordance with examples of the disclosure, the conduit inlet of the mixer conduit can be disposed in the floor of the first channel. In such examples the conduit inlet can be positioned in floor of the first channel such that flow path for the second gas can be maximized. FIG. 5 illustrates a plan view of the upper surface 202 of the mixer block 124 including the groove 210 which comprises a portion of the first channel (i.e., when the inlet block is mounted). As illustrated by dashed lines in FIG. 5 (to denote internal structure) one or more gas inlet channels (e.g., a first gas inlet channel 118 and a second gas inlet channel 120) can be disposed within the mixer block 124 extending from the mixer block side surface 204 to the groove 210 which comprises a portion of the first channel 702. In some embodiments the injection point 502 (or injection points) of the gas inlet channels into the groove 210 (and hence the first channel 702) can separated from the conduit inlet 718 of the mixer conduit 716 by a radial arc of more than 180 degrees, more 200 degrees, more 240 degrees, more 270 degrees, more 300 degrees, more than 330 degrees, or more. In some embodiments of the injection point 502 of the gas inlet channel(s) into the groove 210 (and hence the first channel 702) can be separated from the conduit inlet 718 by a radial arc of between 180 and 330 degrees, between 200 and 300 degrees, or between 240 and 280 degrees.

In accordance with examples of the disclosure, the mixer conduit 716 can orientated vertically, or substantially vertically, within the mixer block 124 (as illustrated in FIG. 5 and FIG. 7). In some embodiments the mixer conduit 716 can be orientated parallel, or substantially parallel, to the central axis 102. In some embodiments the mixer conduit 716 can be orientated parallel to, or substantially parallel to the bore 106. In some embodiments the conduit inlet 718 can be disposed directly above the conduit outlet 720. For example, and referring to both FIG. 5 and FIG. 6, the position of the conduit inlet 718 (FIG. 5) disposed in the groove 210 and (hence the first channel 702) can be located at the same location as the conduit outlet 720 (FIG. 6) disposed in the annular groove (and hence the second channel 708). FIG. 7 further illustrates the conduit inlet 718 being disposed directly above the conduit outlet 720.

In accordance with examples of the disclosure, the first gas injected through the bore and the second gas injected through the gas inlet channel into the mixer block can be brought together to allow for mixing of the first gas with the second gas to form a gas mixture. In various embodiments and with reference to FIG. 7 the manifold assembly 100 further comprises a gas mixing plenum 724 disposed between the inner lower surface 302 of the mixer block 124 and the upper surface of the transfer block 710. In such embodiments the gas mixing plenum 724 can be in fluid communication with the bore through which the first gas is introduced and also in fluid communication with the second channel outlet 722 through which the second gas is introduced. The gas mixing plenum 724 is sized and arranged such the first gas and the second gas are efficiently mixed in the gas mixing plenum prior to feeding the gas mixture to the transfer block and subsequently to the output of the manifold assembly.

In accordance with examples of the disclosure, the manifold assembly 100 can also comprise a transfer block constructured and arranged for transferring the gas mixture from the gas mixing plenum to the output of the manifold body and subsequently on to a reaction chamber coupled to the manifold assembly 100. As illustrated in FIG. 1 the transfer block 126 comprises a transfer conduit 134 which comprises a portion of the bore 106. In various embodiments the transfer conduit 134 disposed within the transfer block 126 comprises a transfer inlet 136 in fluid communication with the gas mixing plenum 724 (as illustrated in FIG. 7). In various embodiments the transfer conduit 134 disposed within the transfer block 126 further comprises a transfer outlet 138 (as illustrated in FIG. 1). In some embodiments the transfer outlet 138 is configured to couple with a reaction chamber to enable the output of the gas mixture (as indicated by gas mixture flow 114) to a reaction chamber.

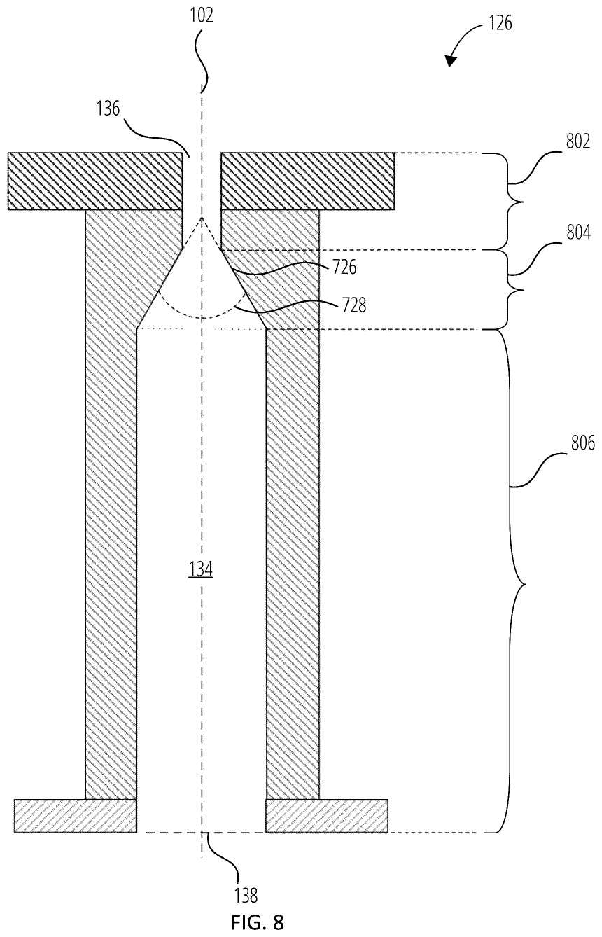

FIG. 8 illustrates a cross sectional view of the transfer block 126 having the central axis 102. The transfer block 126 comprises the transfer conduit 134 disposed with the transfer block 126, the transfer conduit 134 including the transfer inlet 136 and the transfer outlet 138.

In accordance with examples of the disclosure, the transfer conduit 134 can comprise three or more zones. In some embodiments the transfer conduit 134 can comprises at least an input zone 802, an expansion zone 804, and a laminar zone 806. In some embodiments the input zone 802 can be adjacent to the mixer block 124 (as illustrated in FIG. 1) and particular the input zone 802 can be adjacent to the gas mixing plenum 724 (as illustrated in FIG. 7). In some embodiments the expansion zone 804 is adjacent to and below the input zone 802. In some embodiments the laminar zone 806 is adjacent to and below the expansion zone 804.

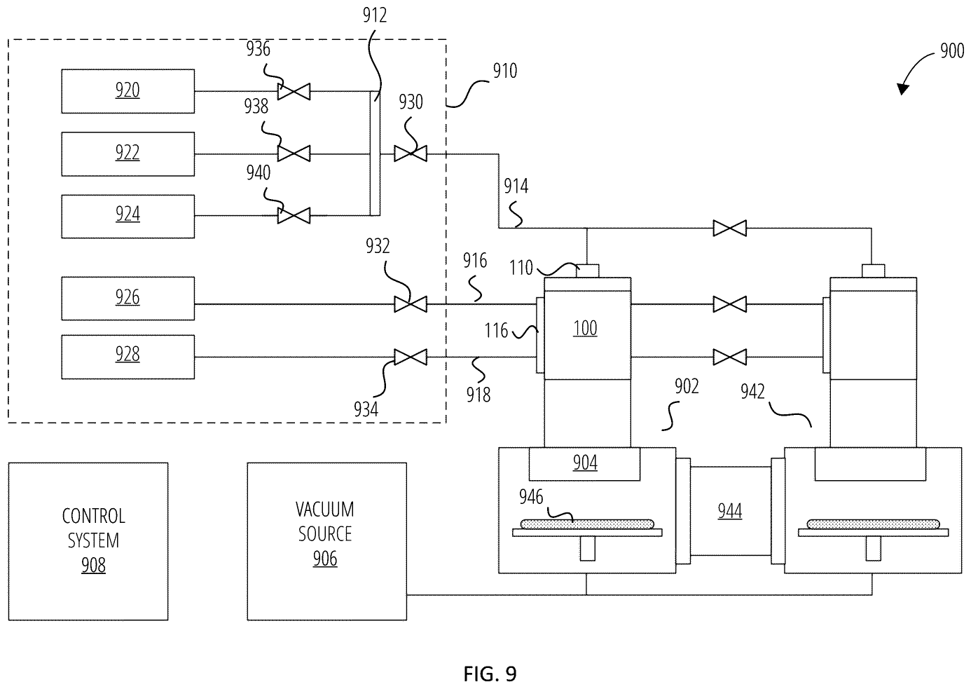

In accordance with examples of the disclosure, the input zone 802 comprises a bore having a first diameter which is configured to receive the gas mixture output from the mixer block (as illustrated in FIG. 7). In some embodiments the diameter of the bore in the expansion zone 804 increases from an initial diameter matching that of the bore diameter in the input zone 802 to a bore diameter which matches the diameter of the bore in the laminar zone 806. In some embodiments the increase in the bore diameter within the expansion zone 804 forms an angled conduit 726 where the angle formed between the angled conduit 726 is illustrated in FIG. 9 as angle 728. In some embodiments angle 728 is greater than 30 degrees, greater than 45 degrees, greater than 60 degrees, greater than 75 degrees, or greater than 90. In some embodiments the angle 728 is between 30 and 90 degrees, between 45 and 75 degrees, or approximately 60 degrees. The laminar zone 806 of the transfer conduit is disposed adjacent to and the below the expansion zone 804. In some embodiments the laminar zone 806 comprises the transfer outlet 138.

The various embodiments of the disclosure also provide reactor system including the manifold assemblies as previously described. FIG. 9 illustrates a reactor system 900 in accordance with at least one embodiment of the disclosure. Reactor system 900 includes a reaction chamber 902, a manifold assembly 100 (as described previously) for supplying a uniform gas mixture to the reaction chamber 902, a vacuum source 906, and a control system 908.

In accordance with examples of the disclosure, reaction chamber 902 can be or include a reaction chamber suitable for gas-phase reactions. Reaction chamber 902 can be formed of suitable material, such as quartz, metal, or the like, and can be configured to retain one or more substrates for processing. Reactor system 900 can include any suitable number of reaction chambers 902 and can optionally include one or more substrate handling systems.

Reaction chamber 902 can be configured as a CVE reactor, a PECVE reactor, an ALE reactor, a CVD reactor, a cyclical deposition process reactor (e.g., a cyclical CVD reactor), an ALD reactor, a PEALD reactor, or the like, any of which may include plasma apparatus, such as direct and/or remote plasma apparatus. In various embodiments the reaction chamber 902 is configured for performing chemical vapor etch process. In various embodiments the reaction chamber 902 may further comprise a gas distribution assembly 904. In such embodiments the manifold assembly 100 and particularly the outlet of the manifold assembly can be coupled to the gas distribution assembly 904. As non-limiting example, the gas distribution assembly 904 may comprise a showerhead gas distribution assembly.

In accordance with examples of the disclosure, the reactor system 900 can comprise a manifold assembly 100 (as described previously described) for supplying a uniform gas mixture to the reaction chamber 902. In some embodiments the manifold assembly 100 comprises a first gas injection port 110 which is supplied with a first gas from a first gas line 914. In some embodiments the manifold assembly 100 can comprise a second gas injection port 116 which can be supplied with a second gas from a second gas line 916. In some embodiments the second gas injection port 116 can be supplied with a third gas from a third gas line 918.

In accordance with examples of the disclosure, the first gas (supplied from the first gas line 914) can be injected into the first gas injection port 110 where it is fed to the bore 106 of the manifold assembly 100 (as illustrated in FIG. 1). The second gas (supplied from the second gas line 916) can be injected into the second gas injection port 116 and supplied to the mixer block 124 via the first gas inlet channel 118 within the manifold body (as illustrated in FIG. 1). In such examples the manifold assembly 100 mixes the first gas and the second gas (e.g., in the gas mixing plenum 724 of FIG. 7) and a uniform gas mixture is output from the manifold assembly 100 to the reaction chamber 902.

In accordance with additional examples of the disclosure, a third gas (supplied from the third gas line 918) can also be injected into the second gas injection port 116 and supplied to the mixer block 124 via the second gas inlet channel 120 within the manifold body (as illustrated in FIG. 1). In such examples, the second gas and the third gas can be at least partially mixed prior to entering the gas mixing plenum 724 within the manifold body (FIG. 7). In such examples the term “second gas” (i.e., the gas feed into the gas mixing plenum to mix the first gas) can comprise a mix of the gases supplied from the second gas line 916 and the third gas line 918.

In accordance with examples of the disclosure, the first gas, the second gas, and the optional third gas can be supplied from a gas source system 910. In such examples the gas source system 910 can comprise two or more source vessels, the gas source system 910 being in fluid communication with the first gas injection port 110 and the second gas injection port 116.

In some embodiments gas source system can comprise a first vessel 920, a second vessel 922, and a third vessel 924, each being in fluid communication with a gas manifold 912. In such embodiments gas flow from the first vessel 920, second vessel 922, and second valve 932 may be metered and/or control by a correspond flow control valve (e.g., valves 936, 938, 940). As a non-limiting example, the first vessel 920 may contain and supply argon, the second vessel 922 may contain and supply water vapor, and the third vessel 924 may contain and supply hydrogen. In such embodiments one or more of the gases supplied from vessels 920, 922, and 930 can be combined in a gas manifold 912. For example, the output of the gas manifold 912 can constitute the first gas which is supplied to the first gas injection ports 110 via first gas line 914. In some embodiments the flow of the output from the gas manifold 912 fed to the first gas line 914 (i.e., the first gas) can be metered and/or controlled by first valve 930.

In some embodiments gas source system 910 can further a fourth vessel 926. In such embodiments the fourth vessel 926 can contain and supply a second gas to the second gas injection port 116, wherein the flow of the second gas fed to second gas line 916 can be metered and/or controlled by a second valve 932. As a non-limiting example, the fourth vessel 926 may contain and supply hydrogen fluoride vapor to the second gas injection port 116 via second gas line 916.

In some embodiments gas source system 910 can further a fifth vessel 928. In such embodiments the fifth vessel 928 can contain and supply a third gas to the second gas injection port 116, wherein the flow of the third gas fed to third gas line 918 can be metered and/or controlled by a third valve 934. As a non-limiting example, the fifth vessel 928 may contain and supply ammonia to the second gas injection port via third gas line 918.

In accordance with examples of the disclosure, the reactor systems 900 can comprise a vacuum source 906 in fluid communication with at the reaction chamber 902. In such examples the vacuum source 906 can be configured for removing an excess of the gas mixture from the reaction chamber 902. In addition, the vacuum source 906 can be configured for controlling the pressure within reaction chamber 902.

In accordance with examples of the disclosure, the reactor systems 900 can comprise a control system 908. In such examples the control system 908 can include a feedback circuit that can electrically connect and communicate via a control lines (e.g., an electrical or optical line or alternatively via wireless communication) with the vacuum source 906, and two or more of the flow control valves, such as the first valve 930 and the second valve 932, for example.

The control system 908 can control and operation the various components of the reactor system 900. In some embodiments the control system 908 can comprise processing electronics configured to control the operation of one or more of the flow control valves, such as the first valve 930 and the second valve 932, for example. In addition, the control system 908 can be configured to communicate with and control the source vessels (920, 922, 924, 926, and 928) and the reaction chamber 902 (and the various components therein). Although illustrated as a single structure in FIG. 9, it should be appreciated that the control system 908 can include a plurality of controllers or sub-systems that have processors, memory devices, and other electronic components that control the operation of the various components of the reactor system 900. As used herein, the term “control system” includes any combination of individual controller devices and processing electronics that may be integrated with or connected to other devices (such as valves, sensors, etc.). Thus, in some embodiments the control system 908 can include a centralized controller that controls the operation of multiple (or all) system components. In some embodiments, the control system 908 can comprise a plurality of distributed controllers that control the operation of one or more system components. Control sequences can be hardwired or programmed into the control system 908.

In accordance with examples of the disclosure, the reactor system 900 may include an additional reaction chamber 942. In such examples the additional reaction chamber 942 may be coupled with the reaction chamber 902 by a transfer chamber 944. For example, the transfer chamber 944 can be constructed and arranged to transfer a substrate (e.g., substrate 946) from the reaction chamber 902 to the additional reaction chamber in a controlled environment.

In accordance with examples of the disclosure, the additional reaction chamber 942 can be configured for performing deposition processes. In such examples the reaction chamber 902 can be configured to perform chemical vapor etch process. In some embodiments substrate 946 disposed within reaction chamber 902 may include an undesirable surface layer, such as, a silicon oxide, for example. In such embodiments the reaction chamber 902 can be configured to perform a chemical vapor etch of the undesirable surface. For example, the gas source system 910 may supply one or more of argon, hydrogen, and water vapor to the first gas injection port 110 of the manifold assembly 100 and the gas source system 910 may further supply one or more of hydrofluoric acid vapor and ammonia to the second gas injection port 116 of the manifold assembly 100. The gases supplied to the manifold assembly 100 are mixed to form the gas mixture which is fed to the reaction chamber 902 to remove the undesirable surface layer from the substrate 946. Subsequently, the substrate 946 can be transferred from the reaction chamber 902 to the additional reaction chamber 942 employing the transfer chamber 944 to ensure the substrate is maintained in a desired state (e.g., free of surface layers and unwanted particles). Upon transfer of substrate 946 to the additional reaction chamber 942 a deposition process may be performed on the substrate 946.

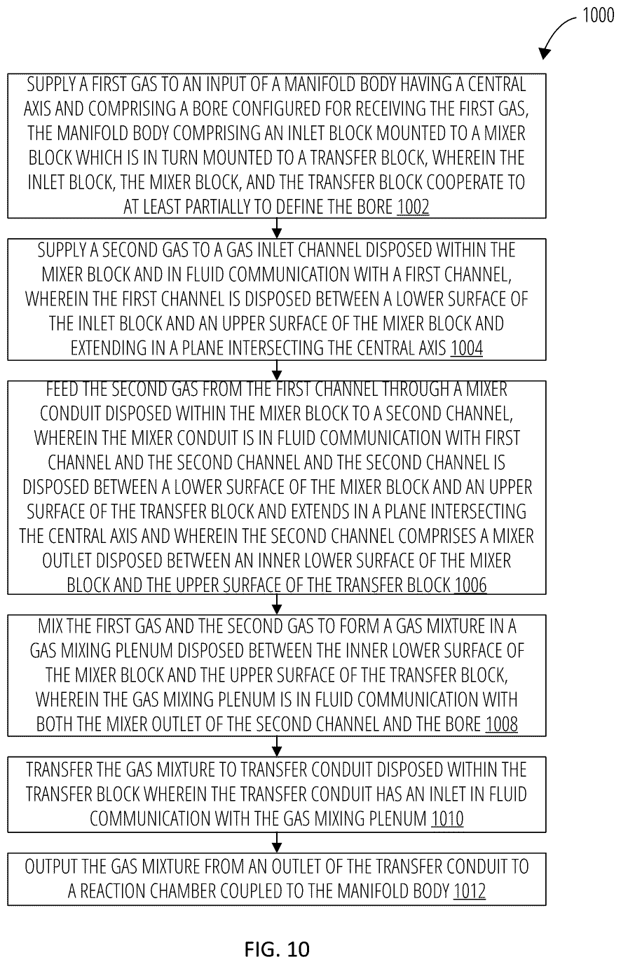

The various embodiments of the disclosure also provide methods for supplying a gas mixture to a reaction chamber. In accordance with examples of the disclosure, FIG. 10 illustrates a method 1000 comprising: supplying a first gas to an input of a manifold body having a central axis and comprising a bore configured for receiving the first gas, the manifold body comprising an inlet block mounted to a mixer block which is in turn mounted to a transfer block, wherein the inlet block, the mixer block, and the transfer block cooperate to at least partially to define the bore (step 1002).

In accordance with examples of the disclosure, the method 1000 further comprises supplying a second gas to a gas inlet channel disposed within the mixer block and in fluid communication with a first channel, wherein the first channel is disposed between a lower surface of the inlet block and an upper surface of the mixer block and extending in a plane intersecting the central axis (step 1004).

In accordance with examples of the disclosure, the method 1000 further comprises feeding the second gas from the first channel through a mixer conduit disposed within the mixer block to a second channel, wherein the mixer conduit is in fluid communication with first channel and the second channel and the second channel is disposed between a lower surface of the mixer block and an upper surface of the transfer block and extends in a plane intersecting the central axis and wherein the second channel comprises a mixer outlet disposed between an inner lower surface of the mixer block and the upper surface of the transfer block (step 1006).

In accordance with examples of the disclosure, the method 1000 further comprises mixing the first gas and the second gas to form a gas mixture in a gas mixing plenum disposed between the inner lower surface of the mixer block and the upper surface of the transfer block, wherein the gas mixing plenum is in fluid communication with both the mixer outlet of the second channel and the bore (step 1008).

In accordance with examples of the disclosure, the method 1000 further comprises transferring the gas mixture to transfer conduit disposed within the transfer block wherein the transfer conduit has an inlet in fluid communication with the gas mixing plenum (step 1010).

In accordance with examples of the disclosure, the method 1000 further comprises outputting the gas mixture from an outlet of the transfer conduit to a reaction chamber coupled to the manifold body.

In some embodiments the reaction chamber is configured to perform chemical vapor etch processes. In some embodiments the first gas comprises one or more of argon, hydrogen, and water vapor, and the second gas comprises one or more of ammonia and hydrofluoric acid vapor. In such embodiments the gas mixture comprises one or more of argon, hydrogen, water vapor, ammonia, and hydrofluoric acid vapor.

In accordance with examples of the disclosure, the method 1000 may further comprises seating a substrate within the reaction chamber, wherein the substrate comprises an undesirable surface layer, such as, a silicon oxide, for example. In some embodiments of method 1000 the gas mixture output to the reaction chamber etches the undesirable surface layer. For example, the gas mixture output to the reaction chamber may remove the undesirable surface layer. In some embodiments of the method 1000 the substrate is subsequently transferred to an additional reaction employing a transfer chamber to ensure the substrate is maintained in a desired state (e.g., free of surface layers and unwanted particles). In some embodiments the method 1000 can further comprise performing a deposition process on the substrate disposed in the additional reaction chamber to form a layer on the substrate.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A manifold assembly comprising:
a manifold body having a central axis and comprising a bore configured for receiving a first gas and outputting a gas mixture to a reaction chamber, the manifold body comprising an inlet block mounted to a mixer block which is in turn mounted to a transfer block, wherein the inlet block, the mixer block, and the transfer block cooperate to at least partially to define the bore;
a first channel disposed between a lower surface of the inlet block and an upper surface of the mixer block and extending in a plane intersecting the central axis;
a gas inlet channel disposed within the mixer block and in fluid communication with the first channel, the gas inlet channel configured for injecting a second gas into the manifold assembly;
a second channel disposed between a lower surface of the mixer block and an upper surface of the transfer block and extending in a plane intersecting the central axis, wherein the second channel comprises a mixer outlet disposed between an inner lower surface of the mixer block and the upper surface of the transfer block;
a mixer conduit disposed within the mixer block between the first channel and the second channel and having a conduit inlet in fluid communication with the first channel and a conduit outlet in fluid communication with the second channel;
a gas mixing plenum disposed between the inner lower surface of the mixer block and the upper surface of the transfer block, the gas mixing plenum in fluid communication with both the mixer outlet and the bore and configured to mix the first gas received from the bore with the second gas received from the mixer outlet to form the gas mixture; and
a transfer conduit disposed within the transfer block and comprising a portion of the bore, the transfer conduit having transfer inlet in fluid communication with the gas mixing plenum and a transfer outlet configured to couple with the reaction chamber to enable the output of the gas mixture to the reaction chamber.

2. The manifold assembly of claim 1, wherein the first channel is defined by a groove formed in the upper surface of the mixer block and by the lower surface of the inlet block.

3. The manifold assembly of claim 2, wherein the first channel is disposed at least partially about the central axis to direct a second gas circumferentially relative to the bore.

4. The manifold assembly of claim 3, wherein the first channel follows a circular curvature.

5. The manifold assembly of claim 4, wherein the first channel extends through an arc of at least 180°.

6. The manifold assembly of claim 5, wherein the first channel extends through an arc of about 240°.

7. The manifold assembly of claim 1, wherein the second channel is at least partially defined by an annular groove formed in the lower surface of the mixer block and by the upper surface of the transfer block.

8. The manifold assembly of claim 1, wherein the first channel and the second channel are radially aligned with each other.

9. The manifold assembly of claim 8, wherein the mixer block comprises a single body of metal.

10. A reactor system comprising:
a reaction chamber;
a manifold assembly coupled with and in fluid communication with the reaction chamber, the manifold assembly comprising:
a manifold body having a central axis and comprising a bore configured for receiving a first gas into the manifold assembly and outputting a gas mixture to the reaction chamber, the manifold body comprising an inlet block mounted to a mixer block which is in turn mounted to a transfer block, where the inlet block, the mixer block, and the transfer block cooperate to at least partially define the bore;
a first channel disposed between a lower surface of the inlet block and an upper surface of the mixer block and extending in a plane intersecting the central axis;
a gas inlet channel disposed within the mixer block and in fluid communication with the first channel, the gas inlet channel configured for injecting a second gas into the manifold assembly;
a second channel disposed between a lower surface of the mixer block and an upper surface of the transfer block and extending in a plane intersecting the central axis, wherein the second channel comprises a mixer outlet disposed between an inner lower surface of the mixer block and the upper surface of the transfer block;
a mixer conduit disposed within the mixer block between the first channel and the second channel and having a conduit inlet in fluid communication with the first channel and a conduit outlet in fluid communication with the second channel;
a gas mixing plenum disposed between the inner lower surface of the mixer block and the upper surface of the transfer block, the gas mixing plenum in fluid communication with both the mixer outlet and the bore and configured to mix the first gas received from the bore with the second gas received from the mixer outlet to form the gas mixture; and
a transfer conduit disposed within the transfer block and comprising a portion of the bore, the transfer conduit having transfer inlet in fluid communication with the gas mixing plenum and a transfer outlet configured to couple with the reaction chamber to enable the output of the gas mixture to the reaction chamber;
a gas source system comprising two or more source vessels, the gas source system being in fluid communication with a first gas injection port and a second gas injection port, the first gas injection port being coupled to a portion of the bore disposed within the inlet block and the second gas injection port being coupled to the gas inlet channel disposed within the mixer block;
a vacuum source in fluid communication with the reaction chamber and configured for removing an excess of the gas mixture from the reaction chamber; and
a controller linked to at least the gas source system, the reaction chamber, the vacuum source, and a first valve configured for controlling flow of the first gas to the manifold assembly and a second valve configured for controlling flow of the second gas to the manifold assembly.

11. The reactor system of claim 10, wherein the first channel extends through an arc of about 240 degrees.

12. The reactor system of claim 11, wherein the first channel and the second channel are radially aligned with each other.

13. The reactor system of claim 12, wherein the reaction chamber further comprising a gas distribution assembly fluidly connected to the transfer outlet of the manifold assembly.

14. The reactor system of claim 13, wherein the reaction chamber is configured for performing chemical vapor etch processes.

15. The reactor system of claim 14, wherein the gas source system further comprises a gas manifold comprising a manifold input and manifold output, wherein the manifold input is in fluid communication with at least two of the source vessels and the manifold output is in fluid communication with the first gas injection port.

16. The reactor system of claim 14, further comprising an additional reaction chamber coupled to the reaction chamber by a transfer chamber, the transfer chamber constructed and arranged to transfer a substrate from the reaction chamber to the additional reaction chamber in a controlled environment.

17. The reactor system of claim 16, wherein the additional reaction chamber is configured for performing deposition processes.

18. A method of supplying a gas mixture to a reaction chamber, the method comprising:
supplying a first gas to an input of a manifold body having a central axis and comprising a bore configured for receiving the first gas, the manifold body comprising an inlet block mounted to a mixer block which is in turn mounted to a transfer block, wherein the inlet block, the mixer block, and the transfer block cooperate to at least partially to define the bore;
supplying a second gas to a gas inlet channel disposed within the mixer block and in fluid communication with a first channel, wherein the first channel is disposed between a lower surface of the inlet block and an upper surface of the mixer block and extending in a plane intersecting the central axis;
feeding the second gas from the first channel through a mixer conduit disposed within the mixer block to a second channel, wherein the mixer conduit is in fluid communication with the first channel and the second channel and the second channel is disposed between a lower surface of the mixer block and an upper surface of the transfer block and extends in a plane intersecting the central axis and wherein the second channel comprises a mixer outlet disposed between an inner lower surface of the mixer block and the upper surface of the transfer block;
mixing the first gas and the second gas to form a gas mixture in a gas mixing plenum disposed between the inner lower surface of the mixer block and the upper surface of the transfer block, wherein the gas mixing plenum is in fluid communication with both the mixer outlet of the second channel and the bore;
transferring the gas mixture to transfer conduit disposed within the transfer block wherein the transfer conduit has an inlet in fluid communication with the gas mixing plenum; and
outputting the gas mixture from an outlet of the transfer conduit to a reaction chamber coupled to the manifold body.

19. The method of claim 18, wherein the reaction chamber is configured to perform chemical vapor etch processes.

20. The method of claim 18, wherein the first gas comprises one or more of argon, hydrogen, and water vapor, the second gas comprises one or more of ammonia and hydrofluoric acid vapor.
